(19) United States
(12) Patent Application Publication
(10) Pub. No.: US 2007/0177744 A1
(43) Pub. Date: Aug. 2, 2007

(54) Automatic volume limiter for portable audio devices

(76) Inventor: Larry Kirn, East Lansing, MI (US)

Correspondence Address: GIFFORD, KRASS, SPRINKLE,ANDERSON & CITKOWSKI, P.C, PO BOX 7021, TROY, MI, 48007-7021, US

(21) Appl. No.: 11/344,358

(22) Filed: Jan. 31, 2006

(51) Int. Cl. H03G 3/00

(52) U.S. Cl. 381/107; 381/104

(57) ABSTRACT

A proximity detector on an audio device to limits the output level when a person's head is detected nearby. Although other detection schemes are anticipated, such a proximity detector may rely upon optical, acoustic, or radio-frequency energy.

### FIELD OF THE INVENTION

This invention relates generally to audio outputs devices and, in particular, to an automatic volume limiter for such devices.

### BACKGROUND OF THE INVENTION

Portable audio devices are becoming ubiquitous and multi-purpose. Resultantly, a single device which produces audio may be used at different distances from the ear of a listener. An extreme example of this would be a device which emits both high-level alarm signals and low-level sound for use pressed against the ear.

Although reliance on user precaution is obvious, it still remains that the potential for hearing damage by inappropriate use increases dramatically with distance variations for a single audio device. The need exists for an automatic system whereby a user is protected from proximal high-level audio.

### SUMMARY OF THE INVENTION

This invention resides in the use of a proximity detector on an audio device to limit the output level when a person's head is detected nearby. Although other detection schemes are anticipated, such a proximity detector may rely upon optical, acoustic, or radio-frequency energy.

### BRIEF DESCRIPTION OF THE DRAWING

FIG. 1 shows a preferred mechanical embodiment of the present invention; and

FIG. 2 shows a partial relevant schematic of a preferred embodiment of the present invention.

### DETAILED DESCRIPTION OF THE INVENTION

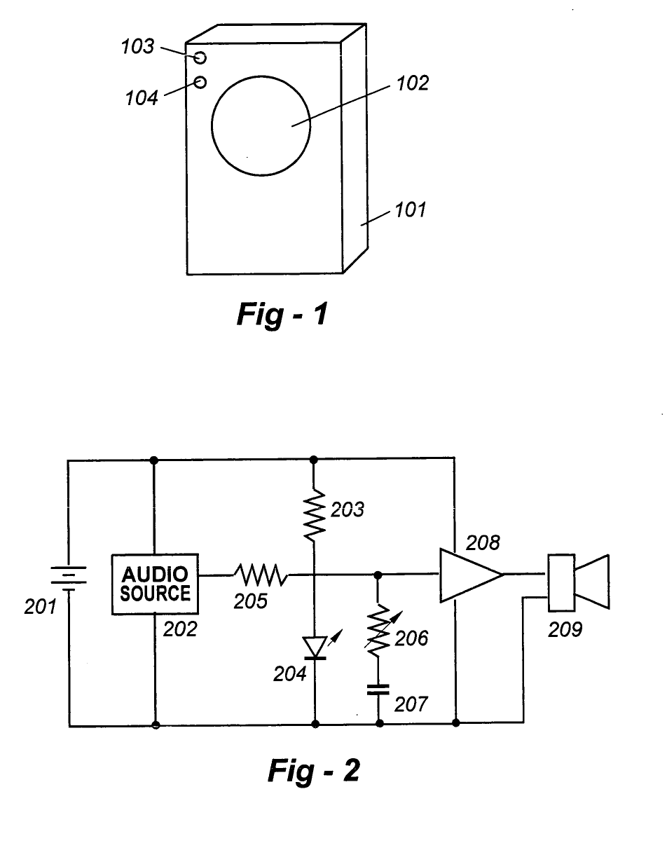

Referring now to FIG. 1, portable audio device 101 is seen to contain loudspeaker 102, infrared emitter 103, and infrared receiver 104. Infrared emitter 103 and receiver 104 are oriented such that receiver 104 will be illuminated by reflected energy from emitter 103 only when a larger object is near both emitter 102 and receiver 103. Note that infrared emitter 103 and receiver 104 are both mounted near speaker 101, in a position to receive reflection when the device is placed near a human head.

Referring now to FIG. 2, the portable audio device of FIG. 1 is powered by a battery 201. Audio from source 202 is passed through resistor 205 to amplifier 208, which powers speaker 209 (speaker 101 of FIG. 1). Battery 201 also provides current for infrared LED 204 (emitter 102 of FIG. 1) through limiting resistor 203. When the value of photocell 206 is much larger than resistor 205, attenuation of the audio input to amplifier 208 is minimal. Reflected LED 204 energy from a large nearby object (such as a head) reduces the resistance of photocell 206 (infrared receiver 103 of FIG. 1), attenuating, through coupling capacitor 207, the audio signal available to amplifier 208. In this fashion, the audio output of the device is limited when in proximity to a head, thus protecting a nearby user from excessive sound levels.

The preferred embodiment herein is chosen for sake of simplicity. Among other approaches, use of the audio output transducer as a sonic proximity detector is anticipated.

I claim:

1. Automatic sound level control apparatus, comprising:
an audio source having a speaker for outputting sound;
one or more devices for detecting the distance from the speaker to a listener; and
circuitry for controlling the volume through the speaker as a function of the distance.

2. The apparatus of claim 1, wherein the devices include an infrared transmitter-receiver.

3. The apparatus of claim 1, wherein the devices include an acoustic transmitter-receiver.

4. The apparatus of claim 1, wherein the devices include an RF transmitter-receiver.

5. The apparatus of claim 1, wherein the circuitry is operative to reduce the volume at the speaker if the distance from the speaker to the listener is less than a predetermined amount.
